(19) United States
(12) Patent Application Publication
(10) Pub. No.: US 2009/0000663 A1
(43) Pub. Date: Jan. 1, 2009

(54) DYE-SENSITIZED SOLAR CELL AND METHOD OF MANUFACTURING THE SAME

(75) Inventors: Byungyou HONG, Gyeonggi-do (KR); Jin Hyo Boo, Gyeonggi-do (KR); Won Seok Choi, Seoul (KR); Yong Seob Park, Gyeonggi-do (KR); Sung Uk Lee, Gyeonggi-do (KR); Eun Chang Choi, Gyeonggi-do (KR); Seong Hun Jeong, Seoul (KR)

Correspondence Address: RABIN & Berdo, PC, 1101 14TH STREET, NW, SUITE 500, WASHINGTON, DC, 20005, US

(73) Assignee: SUNGKYUNKWAN UNIVERSITY FOUNDATION FOR CORPORATE COLLABORATION, Gyeonggi-do (KR)

(21) Appl. No.: 12/028,548

(22) Filed: Feb. 8, 2008

(30) Foreign Application Priority Data
Apr. 4, 2007 (KR) 10-2007-0033488

(51) Int. Cl. H01L 31/00; B05D 5/12; H01M 4/88; C23C 16/513

(52) U.S. Cl. 136/263; 427/74; 427/577

(57) ABSTRACT

Provided are to a dye-sensitized solar cell and method of manufacturing the same. The dye-sensitized solar cell includes a lower electrode having a carbon nanorod layer, and a dye layer provided between an upper electrode and the lower electrode and which includes a carbon nanotube.

The present application claims priority under 35 U.S.C. 119 to Korean Patent Application No. 10-2007-0033488 (filed on Apr. 4, 2007), which is hereby incorporated by reference in its entirety.

### TECHNICAL FIELD

Embodiments relates to a dye-sensitized solar cell and method of manufacturing the same; and, more particularly, to a dye-sensitized solar cell and a method of manufacturing the same according to a conductive carbon nanorod electrode and carbon nanotube doping.

### BACKGROUND

By way of precaution against the exhaustion of fossil fuel, exploitation of various substitute energy sources has been watched worldwide. Also, with the effectuation of Kyoto Protocol in 2005, countries that ratify this protocol should reduce the emission of CO₂.

Among the substitute energy sources, a solar cell has attracted considerable attention as a clean energy since it changes solar energy to electric energy without environmental contamination.

The production of a silicon solar cell is in a high degree of energy conversion efficiency, however there is a problem of high production cost since manufacturing equipment of a solar cell is very expensive. Therefore, as a next best thing, an organic solar cell is now under the middle of study using a reel-to-reel printing technology, of which the energy conversion efficiency is lower than the silicon solar cell but the much lower manufacturing cost can be expected.

That is, with the advantage of which the manufacturing cost of the organic solar cell is lower than that of an inorganic solar cell, it is possible to have various applications of the organic solar cell such as a roll-up type solar cell, a transparent-window solar cell, etc. However, low efficiency has been indicated as the real issue as before.

To develop the efficiency of the organic solar cell, many researches are being carried out centering on upper and lower electrodes of the cell and an organic matter provided between the electrodes.

However, an organic matter of the organic solar cell has low electric charge mobility and thus an electric charge is trapped by impurities and defects of the organic matter and this directly affects the electric charge mobility which is closely related to the efficiency of the solar cell.

### SUMMARY

In order to solve the above problems, embodiments provide a solar cell that includes a carbon nanorod electrode which has better physical characteristic than a metallic electrode and a method of manufacturing the same.

Embodiments also provide a solar cell including a dye layer having a carbon nanotube and a method of manufacturing the same to improve the low electric charge mobility of the conventional organic solar cell.

Embodiments also provide nano metal doping effect to adjust a static bandgap which is able to regulate variation of solar cell efficiency and optical characteristic.

Embodiments have been proposed in order to improve the performance of a solar cell and provide a method of manufacturing the solar cell.

In Embodiments, a dye-sensitized solar cell includes a lower electrode which comprises a carbon nanorod layer; and a dye layer provided between an upper electrode and the lower electrode and which comprises a carbon nanotube.

Here, the lower electrode may have a structure of which the carbon nanorod layer is placed on a fluorine doped-Tin Oxide (FTO) board in layer.

The carbon nanorod layer may be grown making use of a catalytic layer as a catalyst, the catalytic layer being placed between the FTO board and the carbon nanorod layer.

The catalytic layer may comprise a Ti metallization layer and a Ni metallization layer.

The Ti metallization layer and the Ni metallization layer may have the thickness of 20 nm and 40 nm, respectively.

The carbon nanorod layer may be grown by using a method of Hot-Filament Plasma Enhanced Chemical Vapor Deposition (HF-PECVD).

The carbon nanorod layer may be provided when ammonia NH₃ and acetylene C₂H₂ are mixed in a ratio of 3:1 and grown at the temperature of 400° C.

A carbon nanorod of the carbon nanorod layer may be 30˜50 nm in diameter and at least 300 nm in length. And, the specific resistance of the carbon nanorod layer may be less than 5 mΩcm.

The carbon nanotube may be grown by using a method of Hot-Filament Plasma Enhanced Chemical Vapor Deposition (HF-PECVD).

The carbon nanotube may be grown by using a Ti/Ni layer of 60 nm as a catalyst.

The carbon nanotube may be provided by which ammonia NH₃ and acetylene C₂H₂ are mixed in 126:47 sccm and grown at the temperature of 600° C.

Here, the carbon nanotube is 80˜100 nm in diameter and at least 5˜6 μm in length.

In another embodiments, a method of manufacturing a dye-sensitized solar cell, includes steps of: a) forming a lower electrode by growing a carbon nanorod layer; b) forming a dye layer by growing a carbon nanotube; c) forming an upper electrode which a conductive oxide is deposited thereon; and d) attaching the upper electrode, the dye layer and the lower electrode layer and injecting an electrolyte between the upper electrode and the lower electrode.

Here, the above step a) may further includes steps of: forming a catalytic layer by depositing Ti and Ni on a Fluorine doped-Tim Oxide (FTO) board; and growing the carbon nanorod layer by using the catalytic layer as a catalyst.

The carbon nanorod layer may be grown by using a method of Hot-Filament Plasma Enhanced Chemical Vapor Deposition (HF-PECVD) and is provided by which ammonia NH₃ and acetylene C₂H₂ are mixed in a ratio of 3:1 and grown at the temperature of 400° C.

In addition, the step b) may further include: growing the carbon nanotube by using a method of Hot-Filament Plasma Enhanced Chemical Vapor Deposition (HF-PECVD); and digesting the grown carbon nanotube into dyes for a certain period to have the carbon nanotube mix and adsorb with the dyes.

Here, to form the carbon nanotube, ammonia NH₃ and acetylene C₂H₂ may be mixed in 126:47 sccm and grown at the temperature of 600° C.

### DRAWINGS

FIG. 1 is a structural diagram of a dye-sensitized solar cell according to an exemplary embodiment of the present invention.

FIG. 2 shows a method of manufacturing a dye-sensitized solar cell according to an exemplary embodiment of the present invention.

FIG. 3 shows a hot-filament Plasma Enhanced Chemical Vapor Deposition (HF-PECVD) which is used to manufacture a carbon nanotube according to the exemplary embodiment of the present invention.

FIG. 4 is a diagram illustrating a lower electrode which includes carbon nanorods according to exemplary embodiment of the present invention.

FIG. 5 is a photo taken by FE-SEM which shows a sectional view of a lower electrode that includes a carbon nanorod layer according to the exemplary embodiment of the present invention.

FIG. 6 shows that carbon nanotube has grown to be mixed with dye according to exemplary embodiment of the present invention.

### DESCRIPTION

Hereinafter, embodiments of the present invention will be described in detail with reference to the accompanying drawings. To help clear understanding, the same reference number will be used for the same means regardless of the figures provided in the description.

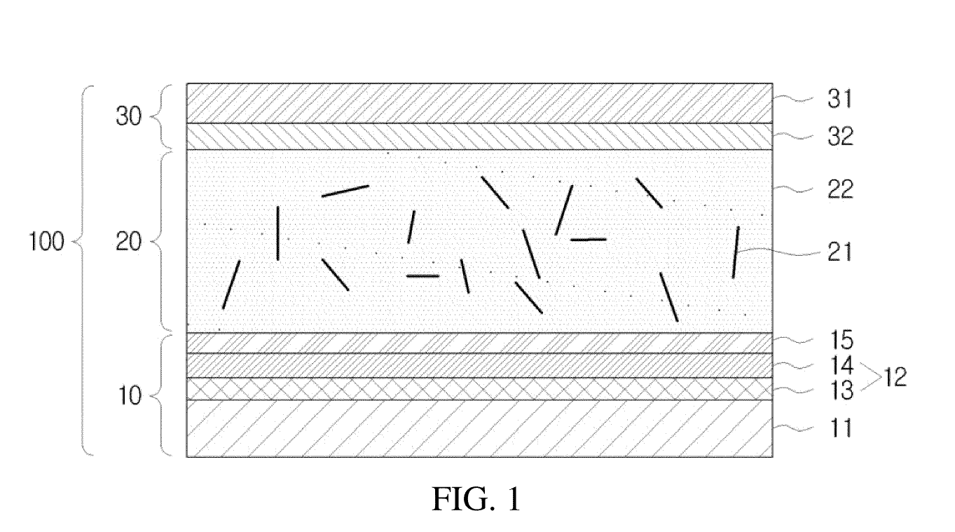

FIG. 1 is a structural diagram of a dye-sensitized solar cell according to an exemplary embodiment of the present invention.

As shown in FIG. 1, a dye-sensitized solar cell 100 includes a lower electrode 10, a dye layer 20, and a upper electrode 30.

The lower electrode 10 comprises a board 11, a catalytic layer 12, and a carbon nanorod layer 15, wherein the catalytic layer 12 is comprised of a Ti metallization layer 13 and a Ni metallization layer 14. Here, the board 11 may be formed as a glass board to which fluorine called as Fluorine doped-Tin Oxide (FTO) is deposited. The Ti metallization layer 13 and Ni metallization layer 14 formed on one side of the board 11 can be deposited in-situ using a magnetron sputtering. A carbon nanorod layer 15 which is formed on the Ti/Ni metallization layers 13, 14 may be formed using a hot-filament Plasma Enhanced Chemical Vapor Deposition (HF-PECVD).

The dye layer 20 may be formed by which carbon nanotube (CNT) 21 is mixed with dyes 22. Here, the Carbon nanotube 21 may be formed by the HF-PECVD and the dyes 22 may be formed as the formula of RuL2(NCS)₂; L=cis-4.4′-dicarboxyl-2.2′-bipyridine.

The upper electrode 30 comprises a board 31 and a conductive oxide 32 which is applied on the board 31. Here, the board 31 may be formed as a glass board to which fluorine called as FTO is deposited, and TiO2 can be used as the conductive oxide 32.

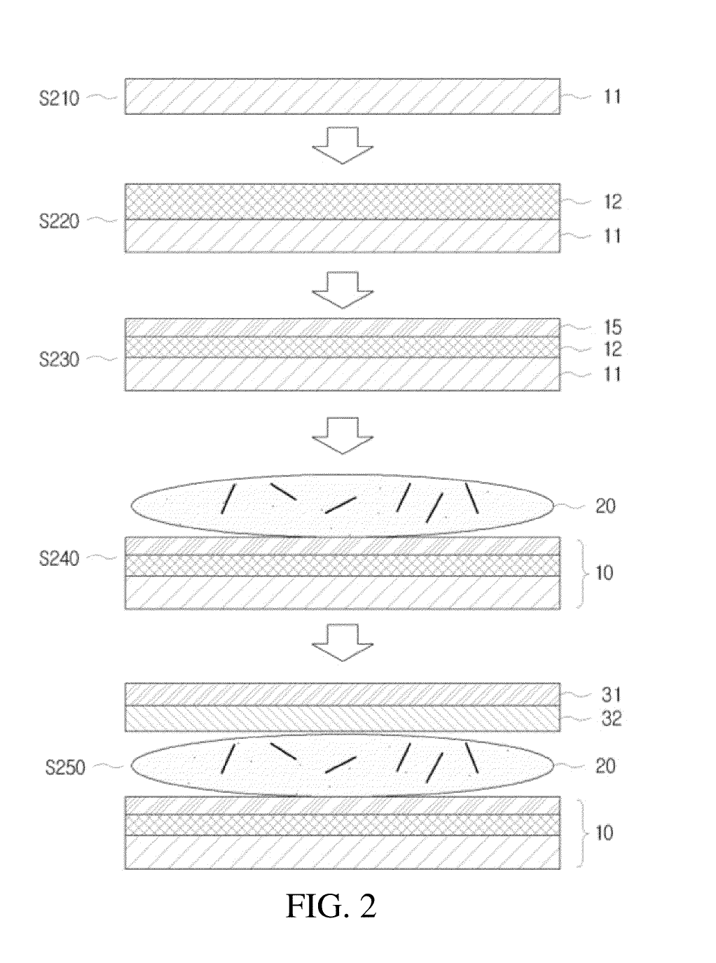

FIG. 2 shows a method of manufacturing a dye-sensitized solar cell according to an exemplary embodiment of the present invention.

The method of manufacturing a dye-sensitized solar cell 100 according to the exemplary embodiment of the present invention comprises forming a lower electrode 10 of which a carbon nanorod layer 15 is formed, forming a dye layer 20 to which a carbon nanotube 21 is added, and forming an upper electrode 30 having the conductive oxide, such as TiO2, deposited thereon.

To examine FIG. 2 in more detail, a step S210 is to place a board 11 in a vacuum chamber and form a vacuum. Here, the board 11 may be formed as a glass board to which fluorine called as Fluorine doped-Tin Oxide (FTO) is deposited.

A step S220 is to in-situ deposit a Ti metallization layer 13 and a Ni metallization layer 14 for thereby forming a catalytic layer 12. Here, deposition pressure is Ar gas atmosphere of 3 m Torr and the DC power applied is 100 W. Also, the deposition time of the Ti metallization layer 13 and Ni metallization layer 14 is 2 min. and 30 sec. and 6 min., respectively, and thickness of the Ti metallization layer 13 and the Ni metallization layer is 20 nm and 40 nm, respectively.

A step S230 is to grow a carbon nanorod layer 15 making use of the HF-PECVD. To form the carbon nanorod layer 15, plasma pre-treatment is applied to a sample to which the catalytic layer is deposited and 120 sccm of ammonia NH₃ and 40 sccm of acetylene C₂H₂ are mixed, that is, in a ratio of 3:1, and it is grown at the temperature of 400° C. Here, the carbon nanorod layer which has fully grown may have a thickness of at least 300 nm.

A step S240 is to grow a carbon nanotube 21 which is to be mixed with dyes using the HF-PECVD. Here, the carbon nanotube 21 is grown at 600° C. at atmosphere of which ammonia NH₃ and acetylene C₂H₂ are mixed in a ratio of 126:47 sccm. Also, a Ti/Ni layer of 60 nm may be used as a catalyst to form the carbon nanotube.

Further, a dye layer 20 is formed by digesting the grown carbon nanotube 21 to the dyes 22 for a certain time, for example, 24 hours, followed to have the carbon nanotube 21 fully mix and adsorb therewith. Here, the dyes 22 may be formed as RuL2(NCS)₂; L=cis-4.4′-dicarboxyl-2.2′-bipyridine.

A step S250 is for forming an upper electrode 30 by coating a conductive oxide to a board 31 in a doctor blade technique. This time, TiO2 may be used as the conductive oxide.

Finally, a step of assembling the upper electrode 30, the dye layer 20, and the lower electrode 10 to make a structure of the dye-sensitized solar cell 100, which includes assembling the upper and lower electrodes and injecting an electrolyte between both electrodes. Here, the electrolyte is a pair of I−/I³⁻ (iodide/triodide, AN-50: oxidation reduction electrolyte) which plays a role of receiving electrons from the lower electrode and transmitting them to the dyes by the action of oxidation reduction.

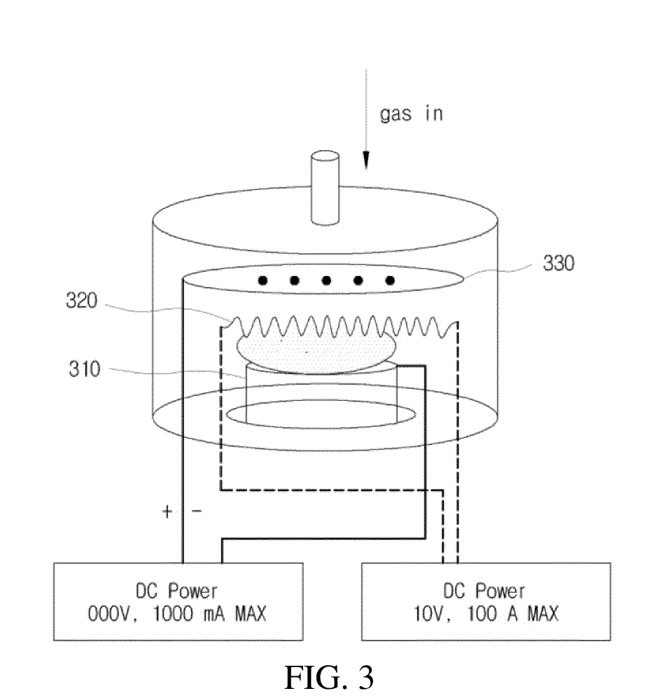

FIG. 3 shows a hot-filament Plasma Enhanced Chemical Vapor Deposition (HF-PECVD) which is used to manufacture a carbon nanotube according to the exemplary embodiment of the present invention.

As shown in FIG. 3, the HF-PECVD is comprised of a board support 310 which is placed in a chamber, a tungsten filament (W-filament) 320, and a gas distributor 330. Here, C₂H₂ and/or NH₃ can be used as reaction gas. Heat applied to the W-filament 320 is closely related to the growth temperature of the carbon nanorod 15 and the carbon nanotube 21, the temperature being controlled between 400 to 600° C.

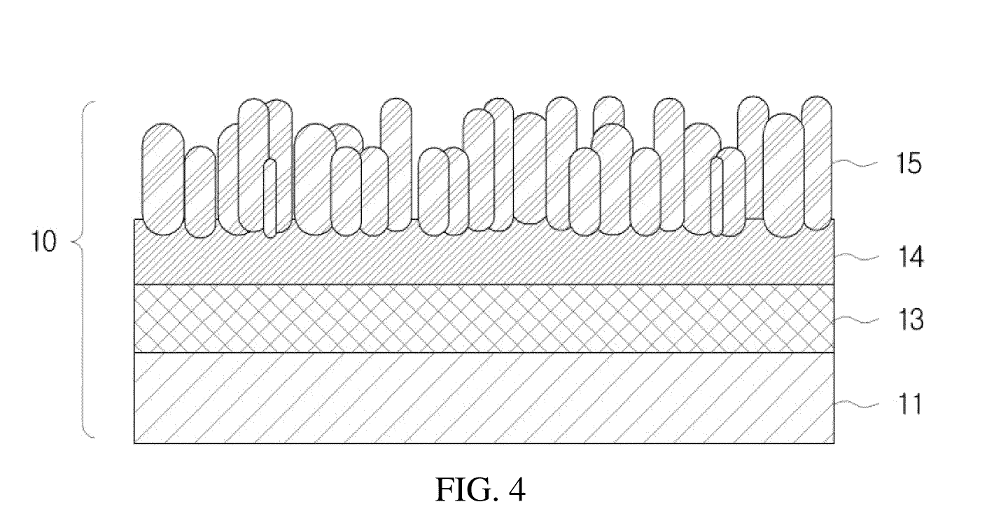

FIG. 4 is a diagram illustrating a lower electrode which includes carbon nanorods according to exemplary embodiment of the present invention.

The lower electrode 10 has the structure of which the Ti metallization layer 13, the Ni metallization layer 14, and the carbon nanorod layer 15 are placed in layer in good order on a fluorine (F)-deposited glass board, the fluorine being called as FTO. The carbon nanorod layer 15 may be formed by the method of HF-PECVD.

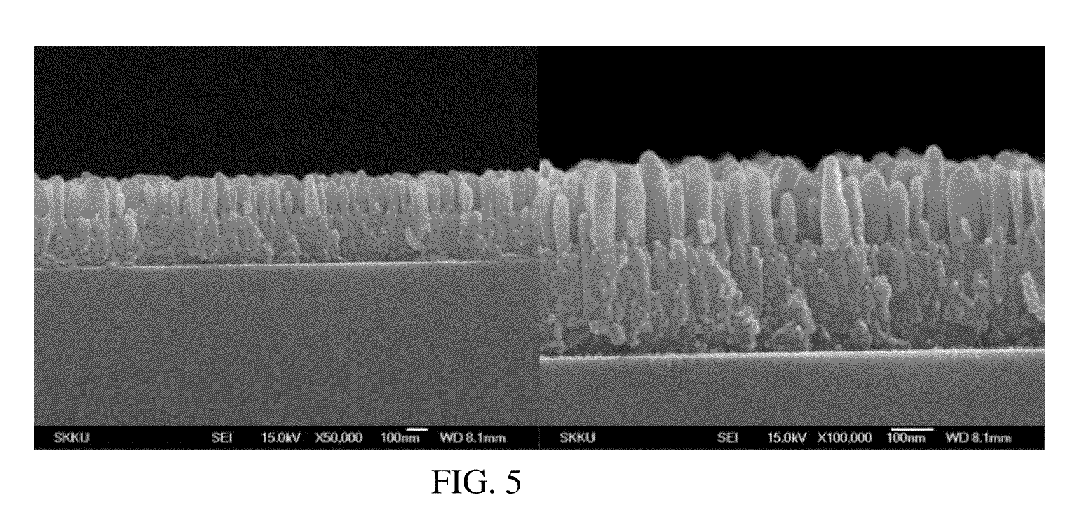

FIG. 5 is a FE-SEM sectional view of a lower electrode which includes a carbon nanorod layer according to the exemplary embodiment of the present invention.

In other words, FIG. 5 is a photo taken by FE-SEM of 10,000 magnifications, illustrating a section of the carbon nanorod layer 15 which has been grown by the manufacturing method described in FIG. 3. As shown therein, the carbon nanorods are densely provided, and a diameter of the carbon nanorod layer 15 is approximately 30 to 50 nm and it is 300 nm in length.

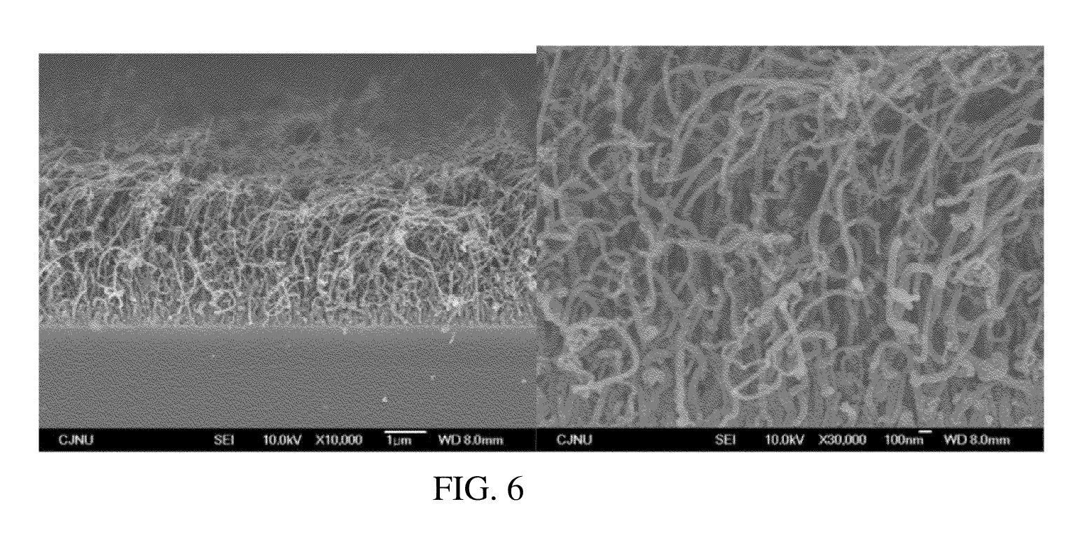

FIG. 6 shows that carbon nanotube has grown to be mixed with dye according to exemplary embodiment of the present invention.

Here, the carbon nanotube has be grown by the method of the HF-PECVD. The diameter and length of the carbon nanotube 21 are 80˜100 nm and 5˜6 μm, respectively. The length of the carbon nanotube 21 should be at least 5˜6 μm.

The explanation has been given in detail with FIG. 1 to FIG. 6. by directly introducing the conductive carbon nanorod and carbon nanotube materials to the dye-sensitized solar cell.

It will be apparent to those skilled in the art that various modifications and variations can be made to embodiments without departing from the spirit or scope of the disclosed embodiments. Thus, it is intended that the present invention covers modifications and variations of this invention provided they come within the scope of the appended claims and their equivalents.

What is claimed is:

1. A dye-sensitized solar cell comprising:
a lower electrode which comprises a carbon nanorod layer; and
a dye layer provided between an upper electrode and the lower electrode and which comprises a carbon nanotube.

2. The dye-sensitized solar cell of claim 1, wherein the lower electrode is provided by which the carbon nanorod layer is placed on a fluorine doped-Tin Oxide (FTO) board in layer.

3. The dye-sensitized solar cell of claim 2, wherein the carbon nanorod layer is grown making use of a catalytic layer as a catalyst, the catalytic layer being placed between the FTO board and the carbon nanorod layer.

4. The dye-sensitized solar cell of claim 3, wherein the catalytic layer comprises a Ti metallization layer and a Ni metallization layer.

5. The dye-sensitized solar cell of claim 4, wherein the Ti metallization layer and the Ni metallization layer have the thickness of 20 nm and 40 nm, respectively.

6. The dye-sensitized solar cell of claim 3, wherein the carbon nanorod layer is grown by using a method of Hot-Filament Plasma Enhanced Chemical Vapor Deposition (HF-PECVD).

7. The dye-sensitized solar cell of claim 6, wherein the carbon nanorod layer is provided by which ammonia NH₃ and acetylene C₂H₂ are mixed in a ratio of 3:1 and grown at the temperature of 400° C.

8. The dye-sensitized solar cell of claim 3, wherein a carbon nanorod of the carbon nanorod layer is 30˜50 nm in diameter and at least 300 nm in length.

9. The dye-sensitized solar cell of claim 1, wherein the specific resistance of the carbon nanorod layer should be less than 5 mΩcm.

10. The dye-sensitized solar cell of claim 1, wherein the carbon nanotube is grown by using a method of Hot-Filament Plasma Enhanced Chemical Vapor Deposition (HF-PECVD).

11. The dye-sensitized solar cell of claim 10, wherein the carbon nanotube is grown by using a Ti/Ni layer of 60 nm as a catalyst.

12. The dye-sensitized solar cell of claim 10, wherein the carbon nanotube is provided by which ammonia NH₃ and acetylene C₂H₂ are mixed in 126:47 sccm and grown at the temperature of 600° C.

13. The dye-sensitized solar cell of claim 10, wherein the carbon nanotube is 80˜100 nm in diameter and at least 5˜6 μm in length.

14. A method of manufacturing a dye-sensitized solar cell, comprising steps of:
a) forming a lower electrode by growing a carbon nanorod layer;
b) forming a dye layer by growing a carbon nanotube;
c) forming an upper electrode which a conductive oxide is deposited thereon; and
d) attaching the upper electrode, the dye layer and the lower electrode layer and injecting an electrolyte between the upper electrode and the lower electrode.

15. The method of claim 14, wherein the step of a) includes:
forming a catalytic layer by depositing Ti and Ni on a Fluorine doped-Tim Oxide (FTO) board; and
growing the carbon nanorod layer by using the catalytic layer as a catalyst.

16. The method of claim 14, wherein the carbon nanorod layer is grown by using a method of Hot-Filament Plasma Enhanced Chemical Vapor Deposition (HF-PECVD).

17. The method of claim 16, wherein the carbon nanorod layer is provided by which ammonia NH₃ and acetylene C₂H₂ are mixed in a ratio of 3:1 and grown at the temperature of 400° C.

18. The method of claim 14, wherein the step of b) includes:
growing the carbon nanotube by using a method of Hot-Filament Plasma Enhanced Chemical Vapor Deposition (HF-PECVD); and
digesting the grown carbon nanotube into dyes for a certain period to have the carbon nanotube mix and adsorb with the dyes.

19. The method of claim 18, wherein the carbon nanotube is provided by which ammonia NH₃ and acetylene C₂H₂ are mixed in 126:47 sccm and grown at the temperature of 600° C.
